(19) United States
(12) Patent Application Publication
(10) Pub. No.: US 2026/0098781 A1
(43) Pub. Date: Apr. 9, 2026

(54) LEAKAGE DETECTION SENSING FOR LIQUID-COOLED SERVERS

(71) Applicant: Super Micro Computer, Inc., San Jose, CA (US)

(72) Inventors: Jian Hou LIANG, San Jose, CA (US); Richard Sinshyun CHEN, San Jose, CA (US); Yaotsan TSAI, San Jose, CA (US)

(21) Appl. No.: 18/926,941

(22) Filed: Oct. 25, 2024

Related U.S. Application Data
(63) Continuation-in-part of application No. 18/906,041, filed on Oct. 3, 2024.

(51) Int. Cl. G01M 3/32; H05K 7/20

(52) U.S. Cl. CPC G01M 3/3245; H05K 7/20254; H05K 7/20272; H05K 7/20781

(57) ABSTRACT

Disclosed are cooling systems and methods for detecting coolant leakage. Processors of servers are attached to cold plates. An internal liquid coolant is contained in a coolant reservoir and is circulated through the cold plates via a coolant distribution manifold. Coolant leakage is detected based at least on a level of the internal liquid coolant in a tapered chamber of the coolant distribution manifold.

### CROSS-REFERENCE TO RELATED APPLICATION

The present application is a continuation-in-part of U.S. application No. Ser. No. 18/906,041, filed on Oct. 3, 2024, which is incorporated herein by reference in its entirety.

### TECHNICAL FIELD

The present disclosure pertains to liquid cooling of electronic devices.

### BACKGROUND

Electronic devices generate significant heat during operation, necessitating cooling systems to prevent overheating. A basic cooling system uses fans to blow air over the heat-generating components of an electronic device. A more advanced cooling method is liquid cooling, where heat is transferred from the electronic device to a liquid coolant, which then carries the heat to an external heat exchanger for heat dissipation. In immersion cooling, the entire electronic device is submerged in a bath of liquid coolant. In contrast, in direct liquid cooling, a component of the electronic device is attached to a cold plate through which the liquid coolant circulates. Although direct liquid cooling is advantageous in certain applications, it poses a risk of coolant leakage that can damage the electronic device.

### BRIEF SUMMARY

In one embodiment, processors of servers are attached to cold plates. An internal liquid coolant is contained in a coolant reservoir and is circulated through the cold plates via a coolant distribution manifold. Coolant leakage is detected based at least on a level of the internal liquid coolant in a tapered chamber of the coolant distribution manifold.

### BRIEF DESCRIPTION OF THE DRAWINGS

FIG. 1 shows a block diagram of a server cooling system, in accordance with an embodiment of the present invention.

FIG. 2 shows an isometric view of a server rack, in accordance with an embodiment of the present invention.

FIG. 3 shows a schematic representation of a coolant distribution manifold, in accordance with an embodiment of the present invention.

FIG. 4 shows a coolant reservoir that contains an internal liquid coolant, in accordance with an embodiment of the present invention.

FIG. 5 shows a schematic representation of direct liquid cooling of a processor, in accordance with an embodiment of the present invention.

FIG. 6 shows a top view of a cold plate that is attached to the processor of FIG. 5, in accordance with an embodiment of the present invention.

FIG. 7 shows a flowchart of a method of detecting leakage of an internal liquid coolant of liquid-cooled servers, in accordance with an embodiment of the present invention.

FIG. 8 shows a flowchart of a method of detecting leakage of an internal liquid coolant of a liquid-cooled server, in accordance with an embodiment of the present invention.

FIG. 9 shows a schematic representation of a coolant distribution manifold, in accordance with another embodiment of the present invention.

FIG. 10 shows a schematic cross-sectional view of a level sensing section of the coolant distribution manifold of FIG. 9, in accordance with an embodiment of the present invention.

FIG. 11 shows a flowchart of a method of detecting leakage of an internal liquid coolant of liquid-cooled servers, in accordance with another embodiment of the present invention.

FIG. 12 shows a block diagram of a computer that may be employed with embodiments of the present invention.

### DETAILED DESCRIPTION

In the present disclosure, numerous specific details are provided, such as examples of systems, materials, components, structures, and methods, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

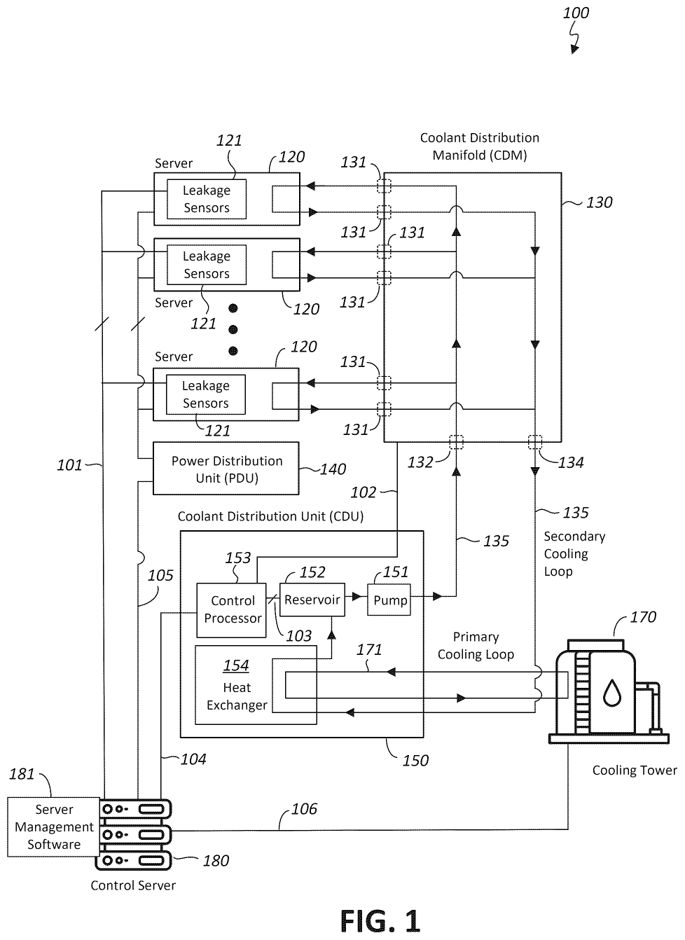

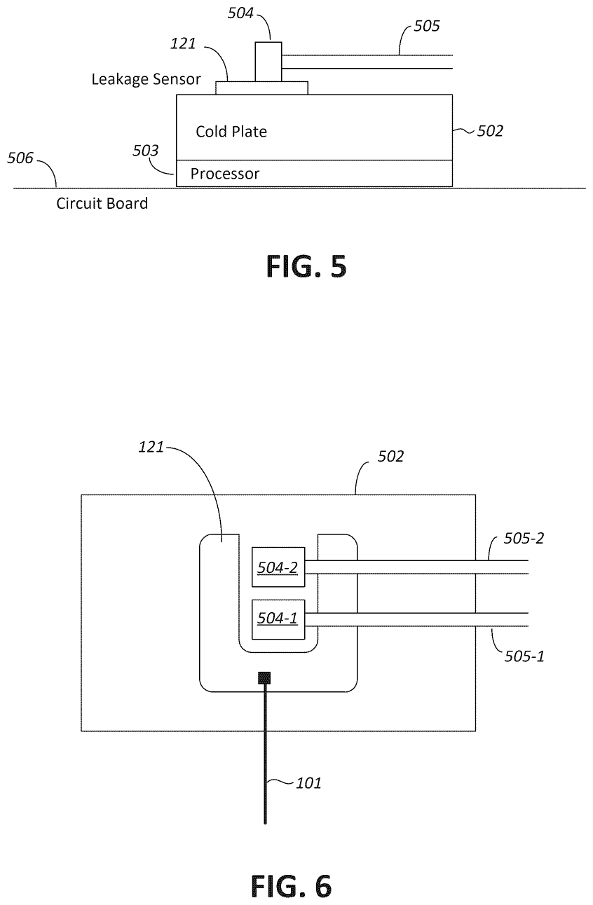

FIG. 1 shows a block diagram of a server cooling system 100, in accordance with an embodiment of the present invention. The cooling system 100 provides liquid cooling to a plurality of servers 120. In one embodiment, the cooling system 100 includes a coolant distribution unit (CDU) 150, a coolant distribution manifold (CDM) 130, and a plurality of cold plates (e.g., see FIGS. 5 and 6, cold plate 502).

In one embodiment, each of the servers 120 is a server computer (i.e., hardware) that has one or more processors that are cooled by direct liquid cooling. Specifically, a processor or other high-power component of a server 120 is attached to a cold plate. An internal liquid coolant is circulated through internal channels of the cold plate. Heat from the processor is thermally conducted to the cold plate, and consequently to the internal liquid coolant. A leakage sensor 121 detects when the internal liquid coolant leaks in the server 120.

The CDU 150 may comprise a pump 151, a coolant reservoir 152, a control processor 153, and a heat exchanger 154. The coolant reservoir 152 contains the internal liquid coolant, which is circulated by the pump 151 in a secondary cooling loop 135. The internal liquid coolant preferably has a low electrical conductivity, e.g., with electrical conductivity less than 5 μs/cm. This way, damage to electronic components is minimized in the event of a coolant leakage. The internal liquid coolant may comprise propylene glycol, water, and additives (e.g., corrosion inhibitor) that together results in electrical conductivity that is less than 5 μs/cm. The particular additives and percent weights of the components of the internal liquid coolant depend on particular cooling requirements.

In the example of FIG. 1, an external liquid coolant (e.g., water) is supplied by a cooling tower 170. The external liquid coolant is circulated in a primary cooling loop 171. Heat from the internal liquid coolant is transferred to the external liquid coolant by the heat exchanger 154.

The CDM 130 distributes the internal liquid coolant to the servers 120. The CDM 130 includes an inlet 132, an outlet 134, and fittings 131. The fittings 131 are connected to plumbing that delivers the internal liquid coolant to cold plates attached to the processors of the servers 120. In the example of FIG. 1, the internal liquid coolant enters through the inlet 132, circulates through the cold plates of the servers 120 via the fittings 131, and exits through the outlet 134 to flow back to the coolant reservoir 152. The heated internal liquid coolant is cooled by the heat exchanger 154 using the external liquid coolant supplied by the cooling tower 170.

In one embodiment, the condition of the cooling tower 170 is reported to a control server 180 (see FIG. 1, line 106) to allow a server management software 181 to monitor the flow rate of the external liquid coolant, the temperature of the external liquid coolant, the pressure in the primary cooling loop 171, and other condition that may affect the operation of the cooling system 100.

A leakage sensor 121 detects leakage of the internal liquid coolant in a server 120. For example, the leakage sensor 121 may be on a cold plate, and sends an alarm when triggered, e.g., when one or more drops of the internal liquid coolant contacts the leakage sensor 121. In one embodiment, a baseboard management controller (BMC) of the server 120 monitors the states of leakage sensors 121 in the server 120, and reports the states of the leakage sensors 121 to the control server 180 (see FIG. 1, lines 101).

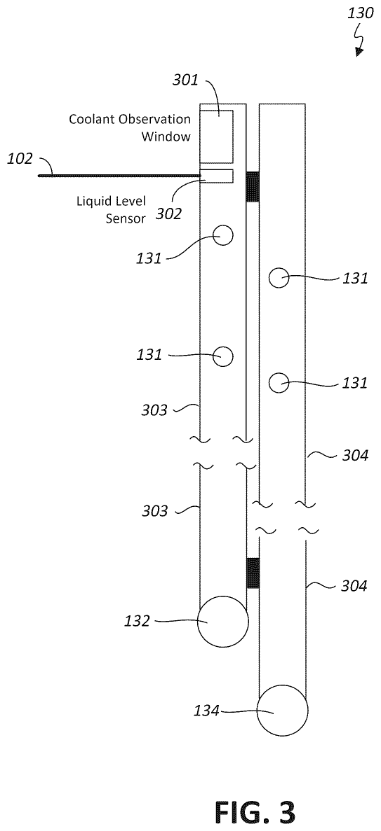

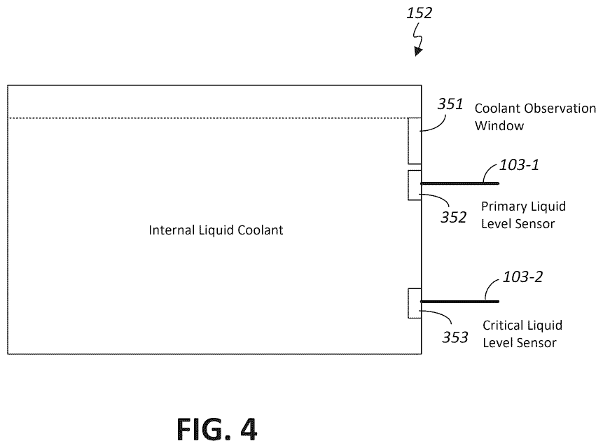

A liquid level sensor monitors the level of the internal liquid coolant in the CDM 130 (see FIG. 3, liquid level sensor 302). At least one other liquid level sensor (see FIG. 4, liquid level sensors 352 and 353) monitors the level of the internal liquid coolant in the coolant reservoir 152. These liquid level sensors of the internal liquid coolant, which are also referred to simply as “coolant level sensors”, are triggered to send an alarm when the level of the internal liquid coolant falls below a predetermined threshold level. The control processor 153 is electrically connected to the coolant level sensors in the CDM 130 (see FIG. 1, line 102) and the coolant reservoir 152 (see FIG. 1, line 103) so that the control processor 153 can detect when they are triggered.

The control processor 153 may be a microcontroller, a central processing unit (CPU), or other processor. The control processor 153 has an associated memory (not shown) that stores instructions for performing functionality of the control processor 153 as described herein. In one embodiment, the control processor 153 is configured to report the states of the coolant level sensors to the control server 180 over a computer network (see arrow 104). Generally, the states of the leakage sensors 121 and coolant level sensors indicate whether or not the sensors have been triggered.

In one embodiment, the control server 180 hosts the server management software 181 that manages the servers 120 as part of a data center. The server management software 181 is configured to detect leakage of the internal liquid coolant based on the states of the leakage sensors 121 and coolant level sensors. The server management software 181 is configured to perform or initiate an intervention in response to detecting leakage of the internal liquid coolant. The intervention depends on the severity of the coolant leakage, which is based on the states of the leakage sensors 121 and the coolant level sensors.

The server management software 181 may, as an intervention, gracefully or immediately shut down the servers 120. A graceful shutdown allows the operating system of a server 120 to properly close all running processes and services, avoiding data corruption or loss, before the server 120 is powered OFF. In contrast, an immediate shutdown immediately powers OFF the server 120. The server management software 181 may send a command to a BMC of a server 120 to gracefully shut down the server 120.

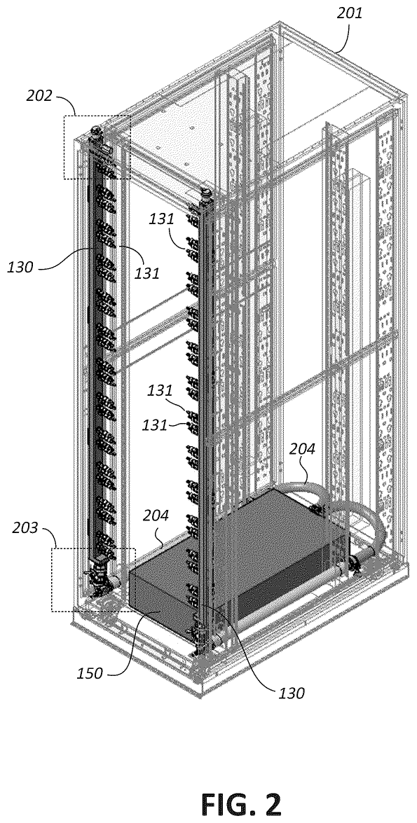

The servers 120 may be installed in a rack (see FIG. 2, rack 201). A power distribution unit (PDU) 140 may provide power to all of the servers 120 in the rack. The server management software 181 may send a command to the power distribution unit 140 (see line 105) to immediately cut off power to, and thus immediately shut down, all of the servers 120 in the rack.

FIG. 2 shows an isometric view of a server rack 201, in accordance with an embodiment of the present invention. The rack 201 has a plurality of levels for accepting servers 120 (not shown in FIG. 2). Shown in FIG. 2 are the CDU 150 and CDMs 130. The CDMs 130 are disposed vertically in the rack 201. The fittings 131 may be quick-connect fittings, for example. Plumbing (not shown; e.g., hoses) connect the fittings 131 to cold plates of corresponding servers 120. The inlet 132 and outlet 134 of the CDM 130 are at the bottom end (see dashed box 203) of a CDM 130. Plumbing 204 (e.g., hoses) connects a CDM 130 to the coolant reservoir 152 in the CDU 150. As will be explained with reference to FIG. 3, the top end (see dashed box 202) of a CDM 130 may have a liquid level sensor for detecting the level of the internal liquid coolant in the CDM 130.

FIG. 3 shows a schematic representation of a CDM 130, in accordance with an embodiment of the present invention. The CDM 130 includes tubes 303 and 304, the fittings 131, the inlet 132, the outlet 134, a liquid level sensor 302, and a coolant observation window 301. The internal liquid coolant enters the inlet 132, flows out of the fittings 131 that are on the tube 303 to circulate through cold plates of the servers 120, exits out of the cold plates to enter the fittings 131 that are on the tube 304, and exits through the outlet 134. In one embodiment, the tubes 303 and 304 are made of stainless steel. The coolant observation window 301 is made of a transparent material (e.g., glass or PVC sheet) that is compatible with the internal liquid coolant. The coolant observation window 301 advantageously allows users to visually check the level of the internal liquid coolant in the CDM 130, which is disposed vertically in the server rack 201 with the liquid level sensor 302 and the coolant observation window 301 positioned toward the top end.

The liquid level sensor 302 serves as a coolant level sensor in the CDM 130. The liquid level sensor 302 is triggered to send an alarm when the level of the internal liquid coolant falls below a predetermined threshold, which in the example of FIG. 3 is set by the position of the liquid level sensor 302 in the tube 303. The liquid level sensor 302 is electrically connected to the control processor 153 (see FIGS. 1 and 3, line 102), allowing the control processor 153 to detect when the liquid level sensor 302 is triggered and so inform the server management software 181. In one embodiment, the server management software 181 raises an alert when the liquid level sensor 302 is triggered. The alert allows users to be notified to visually inspect the level of the internal liquid coolant through the observation window 301 and refill the internal liquid coolant as needed.

It is to be noted that permeation from the tubes 303 and 304, or other normal conditions, can lead to a gradual loss of the internal liquid coolant, causing the liquid level sensor 302 to trigger. Triggering of the liquid level sensor 302 thus typically means that the internal liquid coolant needs to be refilled. However, in the event of a leak, the level of the internal liquid coolant can decrease more rapidly, which is used in embodiments of the present invention to verify the triggering of a leakage sensor 121 that detected the leak.

FIG. 4 shows the coolant reservoir 152, in accordance with an embodiment of the present invention. In the example of FIG. 4, the coolant reservoir 152 includes an observation window 351 that allows users to visually check the level of the internal liquid coolant in the coolant reservoir 152 in the CDU 150. The coolant reservoir 152 further includes a primary liquid level sensor 352 and a critical liquid level sensor 353 for electrically monitoring the level of the internal liquid coolant. The primary liquid level sensor 352 is triggered to send an alarm when the level of the internal liquid coolant falls below a predetermined threshold level, which in the example of FIG. 4 is set by the position of the primary liquid level sensor 352 in the coolant reservoir 152. Similarly, the critical liquid level sensor 353 is triggered to send an alarm when the level of the internal liquid coolant falls below a predetermined threshold level, which in the example of FIG. 4 is set by the position of the critical liquid level sensor 353 in the coolant reservoir 152. The primary liquid level sensor 352 and the critical liquid level sensor 353 are electrically connected to the control processor 153 (see FIG. 1, lines 103; FIG. 4, lines 103-1, 103-2) so that the control processor 153 can detect when they are triggered.

In the example of FIG. 4, the critical liquid level sensor 353 is positioned much lower than the primary liquid level sensor 352. For example, in a coolant reservoir 152 that holds 5 liters of internal liquid coolant, the triggering of the primary liquid level sensor 352 may indicate loss of 1 liter of the internal liquid coolant, and triggering of the critical liquid level sensor 353 may indicate loss of 4 liters of the internal liquid coolant. Whereas triggering of the primary liquid level sensor 352 typically indicates that the internal liquid coolant simply needs to be refilled, triggering of the critical liquid level sensor 353 indicates a substantial loss of the internal liquid coolant and thus requires immediate intervention.

FIG. 5 shows a schematic representation of direct liquid cooling of a processor 503 of a server 120, in accordance with an embodiment of the present invention. The processor 503 may be a central processing unit (CPU), graphics processing unit (GPU), or other high-power integrated circuit. The processor 503 is mounted on a circuit board 506 of the server 120. The circuit board 506 may be a printed circuit board (PCB) that serves as a motherboard. A cold plate 502 is attached to the processor 503. Plumbing 505 (e.g., hose) delivers the internal liquid coolant to the cold plate 502 by way of a liquid port 504 of the cold plate 502. A leakage sensor 121 is disposed in the vicinity of the interface between the port 504 and the plumbing 505 to detect when the internal liquid coolant leaks at the interface. The leakage sensor 121 may be a resistive, capacitive, or other type of sensor that detects when one or more drops of the internal liquid coolant fall on the leakage sensor 121. The state of the leakage sensor 121 is communicated to the control server 180 (see FIG. 1, lines 101; FIG. 6, line 101), for example by the BMC of the corresponding server 120, to allow the server management software 181 to be notified when the leakage sensor 121 is triggered.

FIG. 6 shows a top view of the cold plate 502 of FIG. 5, in accordance with an embodiment of the present invention. In the example of FIG. 6, the internal liquid coolant flows from the CDM 130, enters an inlet port 504-1 of the cold plate 502 via the plumbing 505-1, circulates through the cold plate 502, exits through an outlet port 504-2 of the cold plate 502, and flows back to the CDM 130 via the plumbing 505-2. The leakage sensor 121 is disposed on the cold plate 502, under the plumbing 505-1 and 505-2. In the example of FIG. 6, the leakage sensor 121 surrounds the interface between a port 504 and a plumbing 505, where coolant leakage is most likely to occur. When the internal liquid coolant leaks at the interface, one or more drops of the internal liquid coolant fall on and trigger the leakage sensor 121.

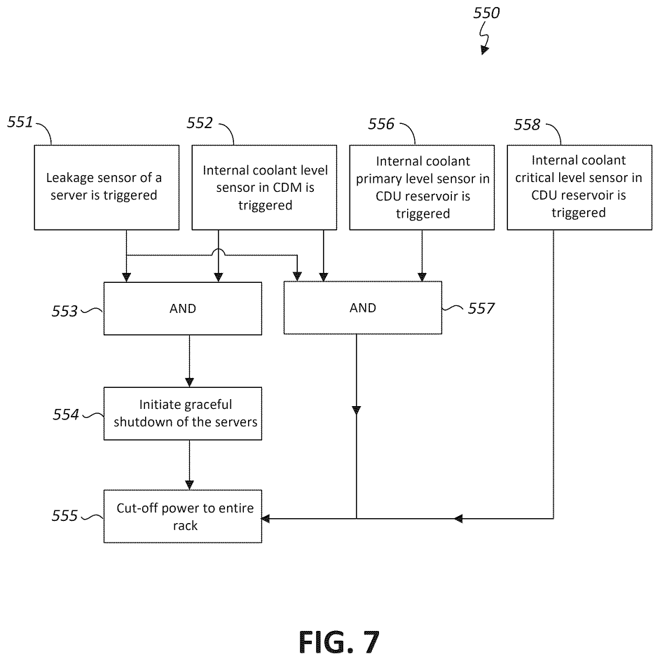

FIG. 7 shows a flowchart of a method 550 of detecting leakage of an internal liquid coolant in liquid-cooled servers, in accordance with an embodiment of the present invention. The method 550 may be performed by the server management software 181 in conjunction with the control processor 153 of the CDU 150 (shown in FIG. 1). As can be appreciated, the method 550 may also be performed by other components without detracting from the merits of the present invention.

In the example of FIG. 7, the states of the leakage sensors 121 of the servers 120, liquid level sensor 302 in the CDM 130, primary liquid level sensor 352 in the coolant reservoir 152, and critical liquid level sensor 353 in the coolant reservoir 152 are monitored. A sensor may be in a triggered state or normal (i.e., non-triggered) state.

When a leakage sensor 121 of a server 120 (FIGS. 7, 551) and the liquid level sensor 302 in the CDM 130 (FIGS. 7, 552) are concurrently in a triggered state (FIG. 7, logical AND operation 553), the server management software 181 initiates a graceful shutdown of all servers 120 in the same rack as the server 120 (FIGS. 7, 554).

It is to be noted that an alarm from a leakage sensor typically indicates that the internal liquid coolant or another liquid has contacted the leakage sensor within the server. In conventional coolant leakage detection systems, an intervention to shut down the server is performed in response to receiving an alarm from the leakage sensor. However, this alarm could be a false alarm, meaning it does not necessarily indicate that the internal liquid coolant is leaking in the server. Specifically, moisture, electrical signal interference, or other unrelated conditions can cause a leakage sensor to trigger. In the method 550, an alarm from a leakage sensor is verified by checking for an alarm from the liquid level sensor of the internal liquid coolant in the CDM 130. This approach advantageously prevents unnecessary shutdowns due to false alarms, thereby avoiding loss of computing time and potential data damage.

The servers 120 may take some time to complete a graceful shutdown. As a safeguard, to avoid permanent damage to the servers 120 when the graceful shutdown takes too long or cannot complete for some reason, the server management software 181 starts a shutdown timer (e.g., five minutes) when graceful shutdown is initiated. The server management software 181 immediately shuts down the servers 120 after expiration of the shutdown timer by cutting off power to the rack that houses the servers 120 (FIGS. 7, 555). In embodiments where the BMC of the server 120 monitors the state of the leakage sensor 121, immediately shutting down the servers 120 after a predetermined time advantageously allows for reporting of the triggering before the BMC is damaged because of the leak. As can be appreciated, it may well be that the graceful shutdown completes to shut down the servers 120 before the expiration of the shutdown timer and power to the rack is cut off.

When a leakage sensor 121 of a server 120 (FIGS. 7, 551), the liquid level sensor 302 in the CDM 130 (FIGS. 7, 552), and the primary liquid level sensor 352 in the coolant reservoir 152 (FIGS. 7, 556) are concurrently in a triggered state (FIG. 7, logical AND operation 557), the server management software 181 immediately shuts down the servers 120 by cutting off power to the rack that houses the servers 120 (FIGS. 7, 555).

To account for possible fluctuations in the level of the internal liquid coolant in the coolant reservoir 152, the server management software 181 may wait for two or more alarms from the primary liquid level sensor 352 before deeming that the primary liquid level sensor 352 has been triggered. For example, after receiving a signal from the control processor 153 that the primary liquid level sensor 352 has been triggered, the server management software 181 may poll the control processor 153 for the state of the primary liquid level sensor 352 at least one more time or wait for the control processor 153 to indicate that the primary liquid level sensor 352 has been triggered at least one more time, within a predetermined time window, to confirm that the primary liquid level sensor 352 has been triggered.

The internal liquid coolant in the coolant reservoir 152 may gradually decrease during normal operation. However, the triggering of a leakage sensor 121, the triggering of the liquid level sensor 302 in the CDM 130, and the triggering of the primary liquid level sensor 352 in the coolant reservoir 152 in the CDU 150 indicate a severe coolant leakage. Accordingly, in that case, the servers 120 are immediately shut down instead of first initiating a graceful shutdown.

When the critical liquid level sensor 353 in the coolant reservoir 152 is triggered (FIGS. 7, 558), the server management software 181 immediately shuts down the servers 120 by cutting off power to the rack that houses the servers 120 (FIGS. 7, 555). Because triggering of the critical liquid level sensor 353 indicates a substantial loss of internal liquid coolant, the servers 120 are immediately shut down regardless of the states of the leakage sensors 121, liquid level sensor 302 in the CDM 130, and primary liquid level sensor 352 in the coolant reservoir 152.

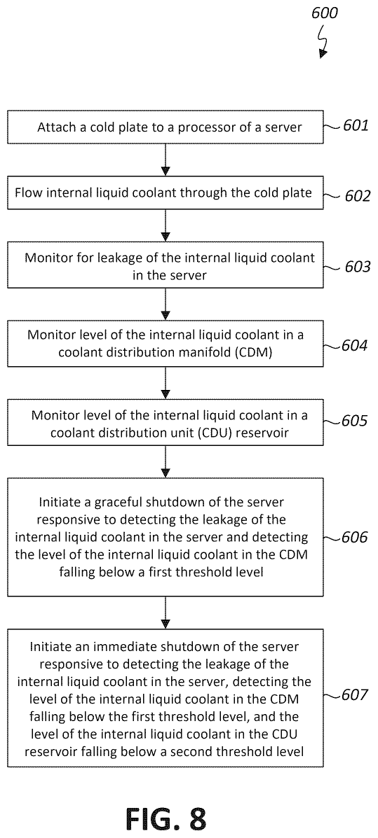

FIG. 8 shows a flowchart of a method 600 of detecting leakage of an internal liquid coolant of a liquid-cooled server, in accordance with an embodiment of the present invention. The method 600 may be performed by a computer, such as the control server 180 running the server management software 181. The method 600 is explained in the context of a single server. As can be appreciated, the method 600 may be performed for a plurality of servers.

In step 601, a cold plate is attached to a processor of a server.

In step 602, an internal liquid coolant is flowed through the cold plate.

In step 603, leakage of the internal liquid coolant in the server is monitored. In one embodiment, a leakage sensor that is attached to the cold plate is triggered responsive to detecting one or more drops of the internal liquid coolant falling on the leakage sensor. The triggering of the leakage sensor causes the leakage sensor to send a corresponding alarm.

In step 604, a level of the internal liquid coolant in a CDM is monitored. In one embodiment, the coolant distribution manifold is disposed vertically in a rack that houses the server and a liquid level sensor in the CDM is triggered to send an alarm when the level of the internal liquid coolant in the CDM falls below a first threshold level.

In step 605, a level of the internal liquid coolant in a CDU reservoir (i.e., coolant reservoir in the CDU) is monitored. In one embodiment, the internal liquid coolant is contained in the CDU reservoir and is flowed through the cold plate by way of the coolant distribution manifold. A liquid level sensor in the CDU reservoir is triggered to send an alarm when the level of the internal liquid coolant in the CDU reservoir falls below a second threshold level.

In step 606, a graceful shutdown of the server is initiated responsive to detecting leakage of the internal liquid coolant in the server and detecting the level of the internal liquid coolant in the CDM falling below the first threshold level.

In step 607, an immediate shutdown of the server is initiated responsive to detecting leakage of the internal liquid coolant in the server, detecting the level of the internal liquid coolant in the CDM falling below the first threshold level, and detecting the level of the internal liquid coolant in the CDU reservoir falling below the second threshold level. In one embodiment, the immediate shutdown of the server is performed by cutting off power to the server.

In some cooling applications, it may be advantageous to sense coolant leakage at a single location rather than at multiple locations of the cooling system. For example, detecting coolant leakage based on the level of the internal liquid coolant in the CDM without necessarily having to rely on detecting coolant leakage in the servers and/or detecting the level of the internal liquid coolant in the CDU reservoir will reduce the number of sensors and complexity of the cooling system. More particularly, in that example, one or more coolant level sensors in the CDM will allow for detecting coolant leakage for an entire rack of servers where the CDM is installed.

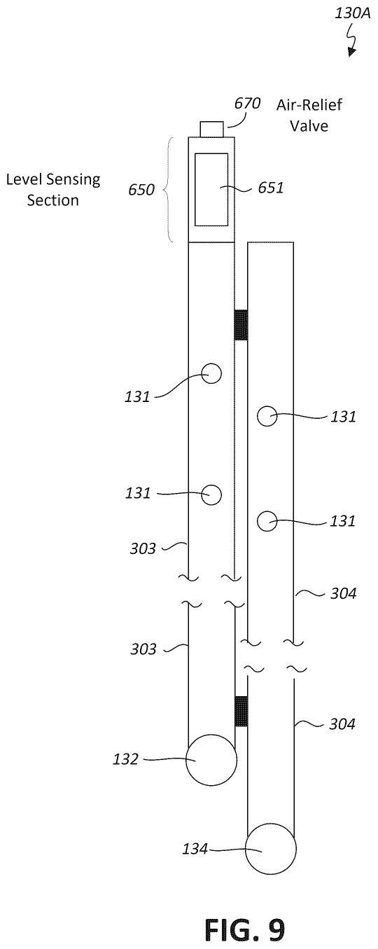

FIG. 9 shows a schematic representation of a CDM 130A, in accordance with an embodiment of the present invention. The CDM 130A is a particular embodiment of the CDM130 of FIG. 3. The CDM 130A is the same as the CDM130 except for the addition of a level sensing section 650 in the CDM 130A. As will be more apparent below, the level sensing section 650 includes a tapered chamber wherein the level of the internal coolant is monitored by one or more liquid level sensors.

In one embodiment, an air relief valve 670 is disposed at the top of the level sensing section 650. The air-relief valve 670 provides air-relief to liquid level sensors in the tapered chamber and air-relief to the secondary cooling loop, so that the detection of the level of the internal liquid coolant in the CDM 130A is not affected by any positive or negative pressure areas in the secondary cooling loop. More particularly, in the event of a coolant leak, the air-relief valve 670 allows trapped air to escape as the internal liquid coolant level decreases, thereby preventing air from becoming trapped in the level sensing section 650 and the secondary cooling loop as a whole, which could otherwise interfere with accurate level sensing or create pressure imbalances within the cooling system. By releasing air, the air-relief valve 670 ensures that liquid level sensors in the level sensing section 650 can continue to monitor the level of the internal liquid coolant accurately, even as the level of the internal liquid coolant drops due to the leak.

In one embodiment, the level sensing section 650 extends from the top of a main section of the CDM 130A, which is the tube 303 in the example of FIG. 9. It is to be noted that the level sensing section 650 may also extend from the top of the tube 304. The level sensing section 650 includes a coolant observation window 651 that is made of a transparent material (e.g., glass or PVC sheet) that is compatible with the internal liquid coolant. The coolant observation window 651 advantageously allows users to visually check the level of the internal liquid coolant in the CDM 130A, which is disposed vertically in a server rack with the level sensing section 650 positioned at the top end.

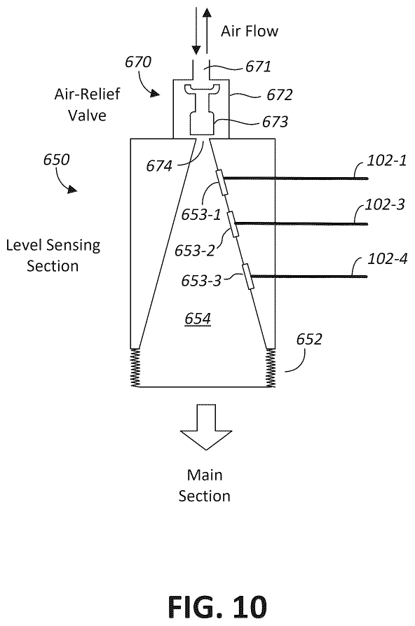

FIG. 10 shows a schematic cross-sectional view of the level sensing section 650, in accordance with an embodiment of the present invention. The level sensing section 650 includes an interface portion 652 that couples to the main section of the CDM 130A, which in one embodiment may be the tube 303 or the tube 304. In the example of FIG. 10, the interface portion 652 is threaded to facilitate direct coupling to main sections of CDMs currently deployed. The interface portion 652 may also be a fitting to allow the level sensing section 650 to be coupled to the main section by plumbing, such as a hose. Additionally, the level sensing section 650 may be integrated with the main section of the CDM 130A, such as in a one-piece design that includes the level sensing section.

The level sensing section 650 may be made of the same material as the main section, such as stainless steel or other material that is compatible with the internal liquid coolant. The level sensing section 650 has a tapered chamber 654 that decreases in volume toward the top. In one embodiment, the chamber 654 forms a cone-shaped funnel with the mouth of the funnel facing toward the main section and the tip of the funnel facing toward a vent of the air-relief valve 670. The tapered shape of the chamber 654 advantageously allows for enhanced coolant level detection sensitivity.

In one embodiment, the level sensing section 650 includes one or more liquid level sensors 653 (i.e., 653-1, 653-2, 653-3) for monitoring the level of the internal liquid coolant in the chamber 654. The liquid level sensors 653 are electrically connected (see FIG. 10, lines 102-1, 102-2, 102-3) to the control processor 153 of the CDU 150 to allow the states of the liquid level sensors 653 to be monitored and reported to the server management software 181.

Each liquid level sensor 653 triggers an alarm when the internal liquid coolant falls below a threshold, which in one embodiment is set by the position of that specific liquid level sensor 653 in the chamber 654. The liquid level sensors 653 may be used to monitor the rate at which the internal liquid coolant decreases. The rate of coolant decrease—from the first threshold level at liquid level sensor 653-1 to the second threshold level at liquid level sensor 653-2, and then to the third threshold level at liquid level sensor 653-3—can be calculated and compared to a threshold rate to detect coolant leakage within the cooling system. A rate of coolant decrease that exceeds the threshold rate indicates coolant leakage. The threshold rate is dependent on the specifics of the cooling system.

In some embodiments, a single liquid level sensor 653 is used to monitor the level of the internal liquid coolant in the chamber 654. In these embodiments, the internal liquid coolant is added to the secondary cooling loop until it reaches a predetermined level in the chamber 654. The single liquid level sensor 653 is then configured such that the decrease of the internal liquid coolant from the predetermined level to the threshold level of the single liquid level sensor 653 corresponds to a coolant loss that indicates coolant leakage. In some embodiments, a single liquid level sensor 653 may be combined with other detection approaches, e.g., leakage sensors inside the servers 120, to prevent false alarms.

The air-relief valve 670 may comprise a body 672 and a float 673. The body 672 has a top vent 671 and a bottom vent 674. Air can move through the vents 671 and 672 to enter or exit the chamber 654. The float 673 keeps the air-relief valve 670 closed during normal operation when the level of the internal liquid coolant in the chamber 654 is sufficient. However, when the level of the internal liquid coolant in the chamber 654 drops in the case of a coolant leak, the float 673 drops and causes the air-relief valve 670 to open and allow air to enter air from the vent 671. Once the internal liquid coolant level rises again, the float 673 causes the air-relief valve 670 to return to its closed position to maintain a sealed system and prevent coolant loss.

In one embodiment, coolant leakage is detected solely based on the level of the internal liquid coolant in the chamber 654. In other words, coolant leakage detection in the chamber 654 does not necessarily need confirmation or validation from a sensor in another location. This advantageously reduces the number of sensors that are needed for leakage detection.

In one embodiment, the server management software 181 may perform coolant leakage detection and perform or initiate intervention based on the level of the internal liquid coolant in the CDM 130A. The server management software 181 may wait for expiration of an initial stabilization period (e.g., 12 hours) before starting leakage detection. After the stabilization period, the server management software 181 may receive the states of the liquid level sensors 653 from the control processor 153 of the CDU 150, and calculate a rate of decrease of the internal liquid coolant in the chamber 654. The server management software 181 may initiate an intervention, such as initiating a graceful shutdown of all servers 120 in the rack where the CDM 130A is installed when the rate of coolant decrease allows for a graceful shutdown. To prevent permanent damage to the servers 120, the intervention may include immediately cutting off power to all servers 120 in the rack when the rate of coolant decrease far exceeds a threshold rate.

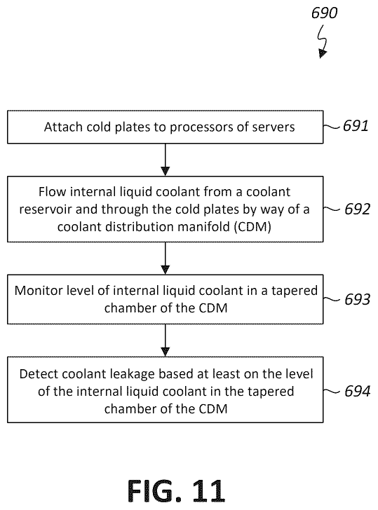

FIG. 11 shows a flowchart of a method 690 of detecting leakage of an internal liquid coolant of liquid-cooled servers, in accordance with an embodiment of the present invention. The method 690 may be performed by the server management software 181 in conjunction with the control processor 153 of the CDU 150 (shown in FIG. 1). As can be appreciated, the method 690 may also be performed by other components without detracting from the merits of the present invention.

In step 691, cold plates are attached to processors of servers.

In step 692, an internal liquid coolant in a coolant reservoir is flowed through the cold plates by way of a CDM.

In step 693, the level of the internal liquid coolant is monitored in a tapered chamber of the CDM. In one embodiment, the tapered chamber forms a cone-shaped funnel. The tapered chamber may be in a level sensing section that is directly and removably (e.g., by threads) connected to a main section of the CDM, is connected to the main section of the CDM by plumbing, or integrated with the main section of the CDM.

In step 694, leakage of the internal liquid coolant is detected based at least on the level of the internal liquid coolant in the tapered chamber of the CDM. In one embodiment, the level of the internal liquid coolant is monitored using one or more liquid level sensors. Coolant leakage is detected when one or more of the liquid level sensors are triggered at a rate indicating a rate of coolant decrease that exceeds a threshold rate. The rate of coolant decrease may be calculated by measuring the time it takes the level of the internal liquid coolant in the tapered chamber to fall from a predetermined level to a threshold level that is set by a single liquid level sensor. The rate of coolant decrease of internal liquid coolant in the tapered chamber may also be calculated by measuring the time it takes the level of the internal liquid coolant to trigger two or more liquid level sensors in the tapered chamber.

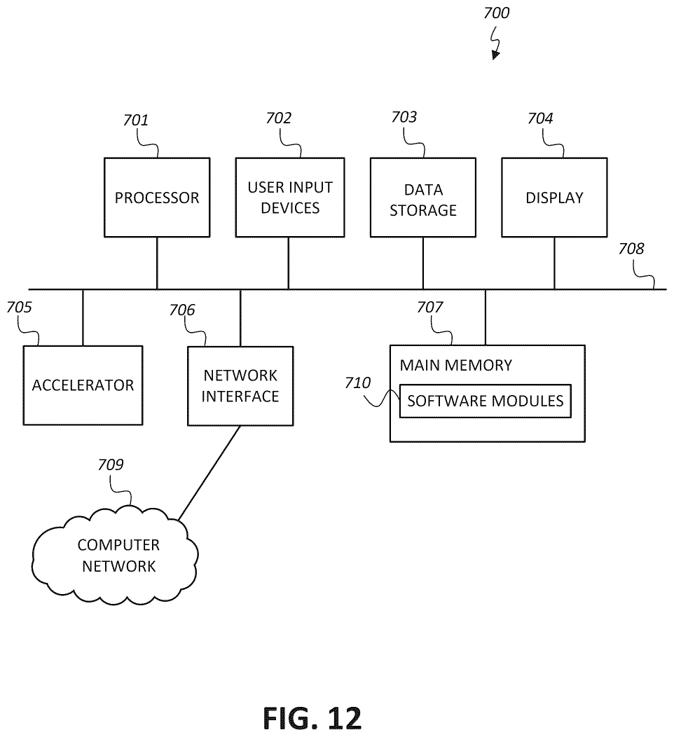

FIG. 12 shows a block diagram of a computer 700 that may be employed with embodiments of the present invention. The computer 700 may be employed as a control server or other computer described herein. The computer 700 may have fewer or more components to meet the needs of a particular application. The computer 700 may include one or more processors 701, one or more user input devices 702 (e.g., keyboard, mouse), one or more data storage devices 703 (e.g., hard drive, optical disk, solid state drive), a display screen 704 (e.g., liquid crystal display, flat panel monitor), one or more accelerators 705 (e.g., graphics processing unit (GPU), neural processing unit (NPU)), a computer network interface 706 (e.g., network adapter, modem), and a main memory 707 (e.g., random access memory). The computer 700 may have one or more buses 708 coupling its various components. The computer network interface 706 may be coupled to a computer network 709.

The computer 700 is a particular machine as programmed with one or more software modules 710, comprising instructions stored non-transitory in the main memory 707 for execution by at least one processor 701 to cause the computer 700 to perform corresponding programmed steps. An article of manufacture may be embodied as computer-readable storage medium including instructions that when executed by at least one processor 701 cause the computer 700 to be operable to perform the functions of the one or more software modules 710. In one embodiment, the software modules 710 includes instructions of a server management software or other piece of software that performs leakage detection and intervention as disclosed herein.

While specific embodiments of the present invention have been provided, it is to be understood that these embodiments are for illustration purposes and not limiting. Many additional embodiments will be apparent to persons of ordinary skill in the art reading this disclosure.

What is claimed is:

1. A cooling system for a plurality of servers, the cooling system comprising:
a plurality of cold plates that are attached to corresponding processors of the plurality of servers;
a coolant reservoir that contains an internal liquid coolant; and
a coolant distribution manifold through which the internal liquid flows from the coolant reservoir to the plurality of cold plates, the coolant distribution manifold having a tapered chamber, a first liquid level sensor that monitors a level of the internal liquid coolant in the tapered chamber, and an air-relief valve that is connected to the tapered chamber.

2. The cooling system of claim 1, wherein leakage of the internal liquid coolant is detected based at least on the level of the internal liquid coolant in the tapered chamber triggering the first liquid level sensor.

3. The cooling system of claim 1, wherein the coolant distribution manifold further comprises a second liquid level sensor that monitors the level of the internal liquid coolant in the tapered chamber, and leakage of the internal liquid coolant is detected based at least on the level of the internal liquid coolant in the tapered chamber triggering the first and second liquid level sensors.

4. The cooling system of claim 3, wherein the triggering of the first and second liquid level sensors indicates a rate of decrease of the internal liquid coolant that exceeds a threshold rate indicative of coolant leakage.

5. The cooling system of claim 1, wherein the tapered chamber forms a cone-shaped funnel.

6. The cooling system of claim 1, wherein the tapered chamber is in a level sensing section of the coolant distribution manifold, and the level sensing section is connected to a main section of the coolant distribution manifold.

7. The cooling system of claim 6, wherein the level sensing section is threaded to the main section.

8. The cooling system of claim 6, wherein the level sensing section is connected to the main section by plumbing.

9. The cooling system of claim 8, wherein the plumbing comprises a hose.

10. The cooling system of claim 1, wherein the coolant distribution manifold is installed vertically in a rack that houses the plurality of servers, the tapered chamber is in a level sensing section of the coolant distribution manifold, and the air-relief valve is disposed on top of the level sensing section.

11. A method of detecting coolant leakage, the method comprising:
attaching cold plates to processors of a plurality of servers;
flowing an internal liquid coolant from a coolant reservoir through the cold plates via a coolant distribution manifold;
monitoring a level of the internal liquid coolant in a tapered chamber of the coolant distribution manifold;
detecting leakage of the internal liquid coolant responsive to the level of the internal liquid coolant in the tapered chamber triggering one or more liquid level sensors; and
initiating an intervention to protect the plurality of servers responsive to detecting the leakage of the internal liquid coolant.

12. The method of claim 11, wherein detecting the leakage of the internal liquid coolant comprises:
triggering a first liquid level sensor responsive to the level of the internal liquid coolant falling below a first threshold;
triggering a second liquid level sensor responsive to the level of the internal liquid coolant falling below a second threshold that is lower than the first threshold;
calculating a rate of decrease of the internal liquid coolant in the tapered chamber based on a time it takes to trigger the first liquid level sensor and the second liquid level sensor; and
detecting the leakage of the internal liquid coolant responsive to the rate of decrease exceeding a threshold rate.

13. The method of claim 11, wherein the intervention includes gracefully shutting down the plurality of servers.

14. The method of claim 11, wherein the intervention includes immediately cutting off power to the plurality of servers.

15. The method of claim 11, wherein the tapered chamber is connected to an air-relief valve.
